(19) United States
(12) Patent Application Publication
(10) Pub. No.: US 2010/0123771 A1
(43) Pub. Date: May 20, 2010

(54) Pixel circuit, photoelectric converter, and image sensing system including the pixel circuit and the photoelectric converter

(75) Inventors: Kyoung Sik Moon, Hwasung-si (KR); Jung Chak Ahn, Yongin-si (KR); Moo Sup Lim, Seoul (KR); Sung-Ho Choi, Seoul (KR); Kang-Sun Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,197

(22) Filed: Nov. 12, 2009

(30) Foreign Application Priority Data
Nov. 14, 2008 (KR) 10-2008-0113501

(51) Int. Cl. H04N 13/02; G01C 3/08

(52) U.S. Cl. 348/46; 356/4.01; 250/208.1; 250/214 R; 348/E13.074

(57) ABSTRACT

Provided are a pixel circuit, a photoelectric converter, and an image sensing system thereof. The pixel circuit includes a photodiode and an output unit. The photodiode generates a first photo charge to detect the distance from an object and a second photo charge to detect the color of the object. The output unit generates at least one depth signal used to detect the distance based on the first photo charge generated by the photodiode, and a color signal used to detect the color of the object based on the second photo charge.

### CROSS-REFERENCE TO RELATED APPLICATIONS

This application claims priority under 35 U.S.C. §119 to Korean Patent Application No. 10-2008-0113501, filed on Nov. 14, 2008, in the Korean Intellectual Property Office (KIPO), the entire contents of which are incorporated herein by reference.

### BACKGROUND

Example embodiments relate to a pixel circuit, and more particularly, to a pixel circuit capable of generating a depth signal and a color signal by using the same photodiode, a photoelectric converter, and an image sensing system including the pixel circuit and the photoelectric converter.

In general, photoelectric converters or image sensors include charge coupled device (CCD) type image sensors and complementary metal-oxide semiconductor (CMOS) type image sensors (CISs). The photoelectric converter includes a plurality of pixels arranged in a 2D matrix format and each pixel outputs an image signal from light energy.

Each of the pixels integrates photo charges corresponding to the quantity of light input through a photodiode and outputs a pixel signal based on the integrated photo charges.

### SUMMARY

Example embodiments provide a pixel circuit capable of generating a depth signal and a color signal by using the same photodiode, a photoelectric converter, and an image sensing system including the pixel circuit and the photoelectric converter.

According to an aspect of example embodiments, there is provided a pixel circuit including a photodiode generating a first photo charge to detect the distance from an object and a second photo charge to detect the color of the object, and an output unit generating at least one depth signal used to detect the distance based on the first photo charge generated by the photodiode, and a color signal used to detect the color of the object based on the second photo charge.

The photodiode may generate the first photo charge based on an optical signal that is generated to detect the distance from the object and reflected from the object.

The output unit may include a depth signal generation unit receiving and storing the first photo charge generated by the photodiode and generating the at least one depth signal based on the stored first photo charge, and a color signal generation unit receiving and storing the second photo charge generated by the photodiode and generating the color signal based on the stored second photo charge.

The depth signal generation unit may include a first transmission transistor controlling transmission of the first photo charge generated by the photodiode to a first floating diffusion node, a first source follower transistor connected between power voltage and a first node and performing source-follower operation on the first node at the power voltage based on the charge stored in the first floating diffusion node, a second transmission transistor controlling transmission of the first photo charge generated by the photodiode to a second floating diffusion node, and a second source follower transistor connected between the power voltage and a second node and performing source-follower operation on the second node at the power voltage based on the charge stored in the second floating diffusion node.

According to another aspect of example embodiments, there is provided a photoelectric conversion unit including a pixel array including a plurality of pixels, wherein each of the pixels generates at least one depth signal used to detect the distance from an object and a color signal of the object, and an image processor generating a 3D image of the object based on the at least one depth signal and the color signal of the object.

Each pixel may generate a first photo charge to detect the distance from the object and a second photo charge to detect the color of the object using a photodiode, generate the at least one depth signal used to detect the distance based on the first photo charge generated by the photodiode, and generate the color signal corresponding to the second photo charge based on the second photo charge.

Each pixel may include a photodiode generating the first photo charge to detect the distance from the object and the second photo charge to detect the color of the object, and an output unit generating the at least one depth signal used to detect the distance based on the first photo charge generated by the photodiode, and a color signal used to detect the color of the object based on the second photo charge.

According to another aspect of example embodiments, there is provided an image sensing system including a photoelectric conversion unit generating an optical signal to measure the distance form an object, generating at least one depth signal to obtained the distance from the object by using a photodiode in response to a reflected optical signal, the reflected optical signal being the optical signal reflected from the object, and detecting a color signal of the object by using the photodiode, and an image processor generating a 3D image of the object based on the at least one depth signal and the color signal detected by the photoelectric conversion unit.

The image sensing system may further include a filter located between the photoelectric unit and a lens filtering each of the reflected optical signal band and the color signal band.

The photoelectric conversion unit may include a transmitted light generation unit generating the generated optical signal, and a pixel array including a plurality of pixels, wherein each of the pixels generates the at least one depth signal and the color signal in response to the reflected optical signal reflected from the object.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram of an image sensing system according to example embodiments;

FIG. 2 illustrates the pixel array of FIG. 1;

FIG. 3 is a functional block diagram of the unit pixel of the pixel array of FIG. 1;

FIG. 4 is a circuit diagram of the unit pixel of the pixel array of FIG. 1;

FIG. 5 is a layout diagram of the unit pixel of the pixel array of FIG. 1;

FIGS. 6A and 6B are cross sectional views taken along the lines I-I′ and II-II′ of FIG. 5;

FIG. 7 is a timing diagram for explaining the operation of the unit pixel of the pixel array of FIG. 1;

FIG. 8 is a graph for explaining the operational characteristic of a stop band filter that may be implemented in the photoelectric converter of FIG. 1;

FIG. 9 is a schematic block diagram of a system including an image sensor according to an exemplary embodiment of the example embodiments; and

FIG. 10 is a flowchart for explaining an image sensing method according to an exemplary embodiment of the example embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

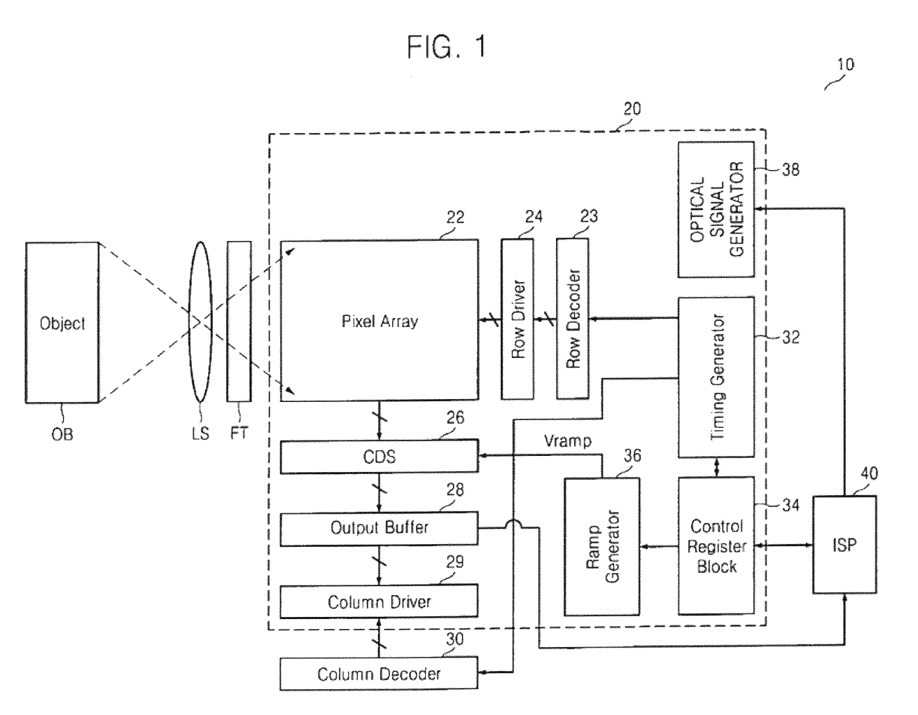

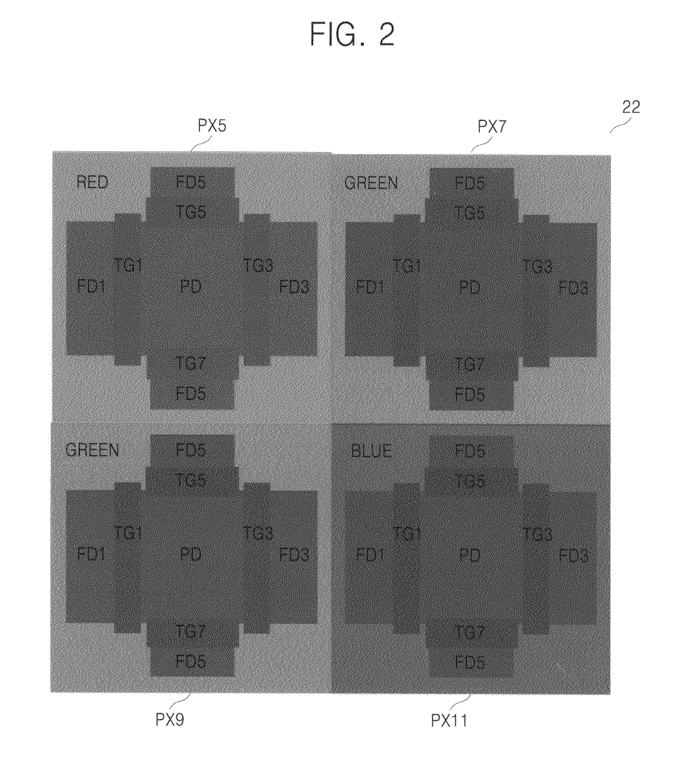

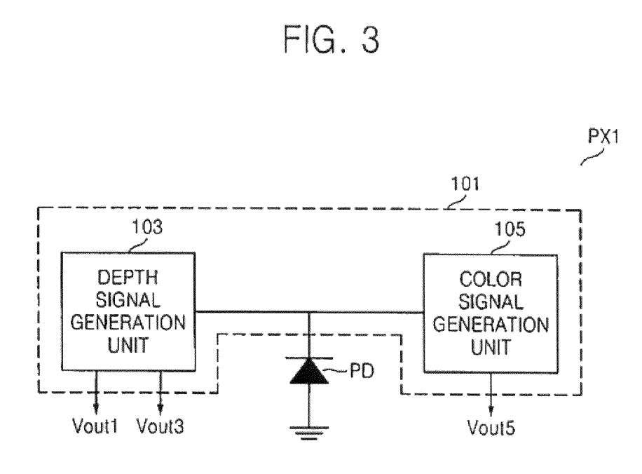

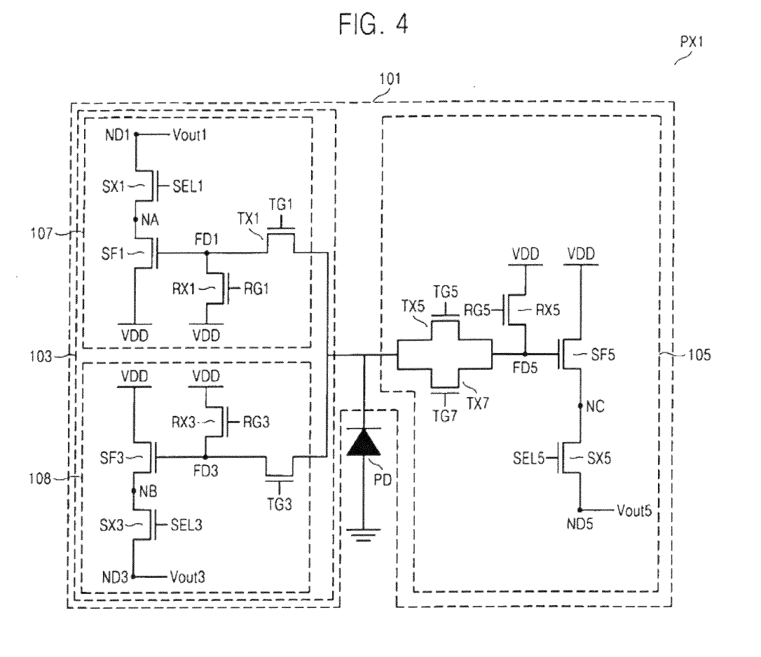

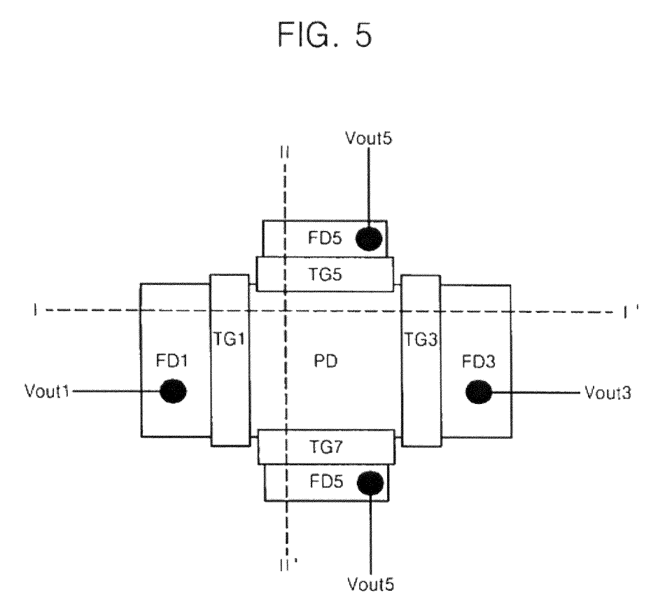

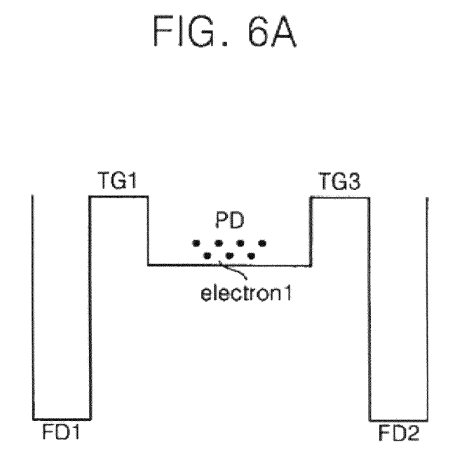

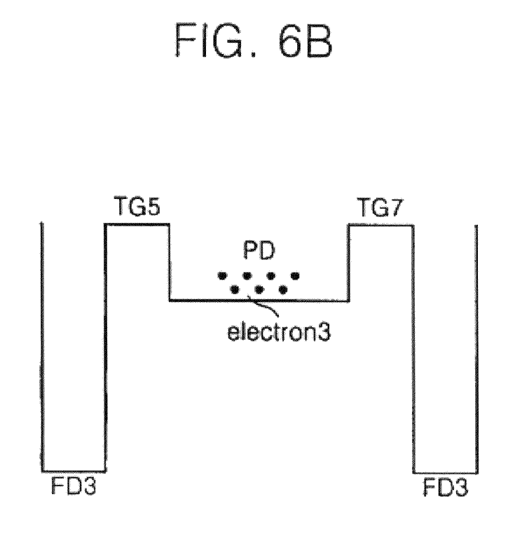

FIG. 1 is a block diagram of an image sensing system according to an exemplary embodiment of example embodiments. FIG. 2 illustrates the pixel array of FIG. 1. FIG. 3 is a functional block diagram of the unit pixel of the pixel array of FIG. 1. FIG. 4 is a circuit diagram of the unit pixel of the pixel array of FIG. 1. FIG. 5 is a layout diagram of the unit pixel of the pixel array of FIG. 1. FIGS. 6A and 6B are cross sectional views taken along the lines I-I′ and II-II′ of FIG. 5.

Referring to FIGS. 1-6, an image sensing system 10 that may be implemented in a digital camera or a mobile phone having digital camera functions may include a photoelectric conversion unit 20 and an image signal processor (ISP) 40. The photoelectric conversion unit 20 and the ISP 40 may be implemented by separate chips or modules.

The photoelectric conversion unit 20 may generate an optical signal to measure the distance from an object OB, generate at least one depth signal to obtain the distance from the OB by using a photodiode (PD), in response to the optical signal being reflected from the OB, and detect a color signal of the OB by using the PD. The photoelectric conversion unit 20 may include an active pixel array 22, a row decoder 23, a row driver 24, a correlated double sampling (CDS) block 26, an output buffer 28, a column driver 29, a column decoder 30, a timing generator (TG) 32, a control register block 34, a ramp signal generator 36, and a optical signal generator 38.

The pixel array 22 may include a plurality of pixels, for example, PX5-PX11 of FIG. 2, in a 2D matrix format, the pixels being connected to a plurality of row lines (not shown) and a plurality of column lines (not shown). Each of the pixels PX5-PX11 may include a red pixel PX5 to convert light in a red spectrum range into an electric signal, green pixels PX7 and PX9 to convert light in a green spectrum range into an electric signal, and a blue pixel PX11 to convert light in a blue spectrum range into an electric signal.

A color filter for transmitting light in a particular spectrum range is arranged above the pixels PX5-PX11 constituting the pixel array 22, as illustrated in FIG. 2. The color filter may include a red color filter for filtering light in a red spectrum range, a green color filter for filtering light in a green spectrum range, and a blue color filter for filtering light in a blue spectrum range.

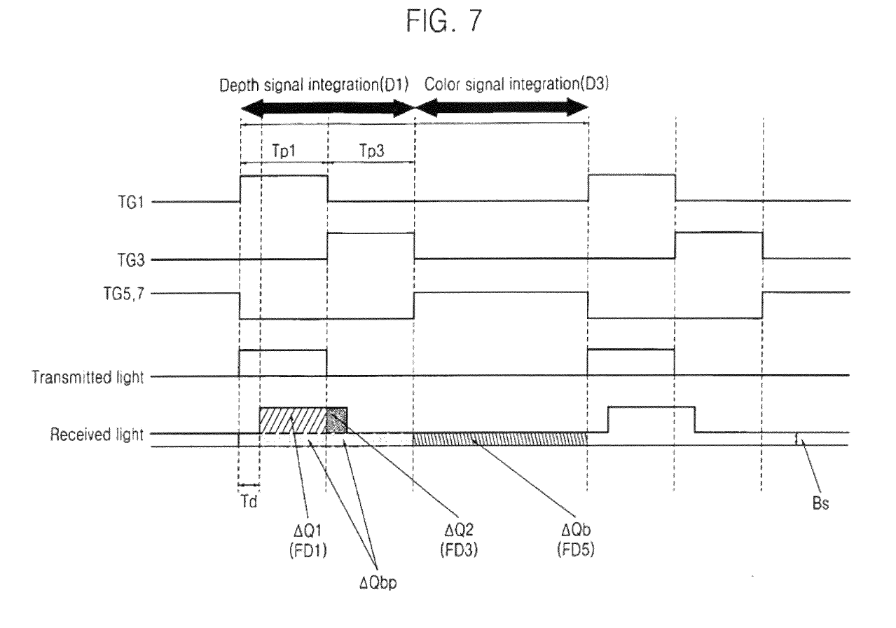

A unit pixel, for example, PX1 of FIG. 3, constituting the pixel array 22 may generate at least one depth signal, for example, Vout1 and Vout3, based on a first photo charge generated by the PD to detect the distance from the OB in a depth signal generation (or integration) mode, for example, D1 of FIG. 7. Also, the unit pixel, for example, PX1 of FIG. 3, may generate a color signal Vout5 based on a second photo charge generated by the PD to detect the color of the OB in a color signal generation (or integration) mode, for example, D3 of FIG. 7.

The unit pixel, for example, PX1 of FIG. 3, constituting the pixel array 22 may include the PD and an output unit 101. The PD may generate the first photo charge to detect the distance from the OB and the second photo charge to detect the color of the OB.

In detail, the PD may generate the first photo charge based on the transmitted light generated by the optical signal generator 38 and reflected from the OB, to detect the distance from the OB. Also, the PD may receive light energy generated by the OB and generate the second photo charge used for generating a color signal.

The output unit 101 may generate the at least one depth signal, for example, Vout1 and Vout3, used for detecting a distance based on the first photo charge generated by the PD, and the color signal Vout5 corresponding to the second photo charge based on the second photo charge. In detail, the output unit 101 may generate the at least one depth signal, for example, Vout1 and Vout3, in the depth signal generation (or integration) mode, for example, D1 of FIG. 7, and the color signal Vout5 in the color signal generation (or integration) mode, for example D3 of FIG. 7.

The output unit 101 may include a depth signal generation unit 103 and the color signal generation unit 105. The depth signal generation unit 103 may receive and store the first photo charge generated by the PD and generate the at least one depth signal, for example, Vout1 and Vout3, based on the first photo charge.

Referring to FIG. 4, in the structure of the depth signal generation unit 103, the depth signal generation unit 103 may include a first depth signal generation block 107 and a second depth signal generation block 108. The first depth signal generation block 107 may receive the first photo charge integrated in the PD during the first time period, for example, Tp1 of FIG. 7, and generate the first depth signal Vout 1 based on the received first photo charge.

The first depth signal generation block 107 may include a first transmission transistor TX1, a first floating diffusion node FD1, a first reset transistor RX1, a first source follower transistor (or a drive transistor) SF1, and a first selection transistor SX1. The TX1 may transmit the charge (or photo current) integrated by the PD to the FD1 in response to a first transmission control signal TG1 input to a gate.

The FD1 is formed into a floating diffusion region and may receive and store the photo charges generated by the PD through the TX1. For example, as it may be seen from FIG. 6A taken along the line II′ of FIG. 5, the FD1 may receive and store the first photo charge “electron1” integrated in the PD during the first time period, for example, Tp1 of FIG. 7, through the TX1.

The RX1 is connected between a power voltage VDD and the FD1 and may reset the FD1 at the VDD in response to a first reset signal RG1. The SF1 is connected between the VDD and a first node NA and may perform source-follower operation on the NA at the VDD based on the charge stored in the FD1.

The SX1 is connected between the NA and a first output node ND1 and may form an electric path between the NA and the ND1 in response to a first selection signal SEL1. The second depth signal generation block 108 may receive the first photo charge integrated in the PD during a second time period, for example, Tp3 of FIG. 7, and generate the second depth signal Vout3 based on the received first photo charge.

The second depth signal generation block 108 may include a second transmission transistor TX3, a second floating diffusion node FD3, a second reset transistor RX3, a second source follower transistor SF3, and a second selection transistor SX3. The TX3 may transmit the charge (or photo current) integrated by the PD to the FD3 in response to a second transmission control signal TG3 input to a gate.

The FD3 is formed into a floating diffusion region and may receive and store the photo charges generated by the PD through the TX3. For example, as it may be seen from FIG. 6A taken along the line II′ of FIG. 5, which is an electric potential barrier diagram, the FD3 may receive and store the first photo charge “electron1” integrated in the PD during the second time period, for example, Tp3 of FIG. 7, through the TX3.

The RX3 is connected between the VDD and the FD3 and may reset the FD3 at the VDD in response to a second reset signal RG3. The SF3 is connected between the VDD and a second node NB and may perform source-follower operation on the NB at the VDD based on the charge stored in the FD3.

The SX3 is connected between the NB and a second output node ND3 and may form an electric path between the NB and the ND3 in response to a second selection signal SEL3.

The color signal generation unit 105 may receive and store the second photo charge generated by the PD and generate a color signal based on the stored second photo charge. The color signal generation unit 105 may include a third transmission transistor TX5, a third floating diffusion node FD5, a third reset transistor RX5, a third source follower transistor SF5, and a third selection transistor SX5.

The TX5 may transmit the charge (or photo current) integrated by the PD to the FD5 in response to a third transmission control signal TG5 input to a gate.

The FD5 is formed into a floating diffusion region and may receive and store the photo charges generated by the PD through the TX5. For example, as it may be seen from FIG. 6B taken along the line II-II′ of FIG. 5, the FD5 may receive and store a second photo charge “electron3” integrated in the PD during color signal generation time, for example, D3 of FIG. 7, through the TX5.

The RX5 is connected between the VDD and the FD5 and may reset the FD5 at the VDD in response to a third reset signal RG5. The SF5 is connected between the VDD and a third node NC and may perform source-follower operation on the NC at the VDD based on the charge stored in the FD5.

The SX5 is connected between the NC and a third output node ND5 and may form an electric path between the NC and the ND5 in response to a third selection signal SEL5. The color signal generation unit 105 may further include a fourth transmission transistor TX7. The TX7 may transmit the charge (or photo current) integrated by the PD to the FD5 in response to a fourth transmission control signal TG7 input to a gate.

FIG. 7 is a timing diagram for explaining the operation of the unit pixel of the pixel array of FIG. 1. Referring to FIGS. 4 and 7, in the operation of the unit pixel PX1, the optical signal generator 38 may generate an optical signal (transmitted light) during the first time period Tp1 of the depth signal generation (or integration) mode D1. The PD may receive the optical signal (received light) reflected from the OB.

The reflected optical signal (received light) is a signal received at the PD when a predetermined or reference delay time Td passes after the optical signal (transmitted light) is generated toward the OB. The PD may include a background charge (or fixed pattern charge BS). The BS is a charge previously generated in the PD before the reflected received light is received by the PD. The BS may be a charge which the PD generates based on light energy generated by the OB, not the reflected optical signal (received light).

During the first time period Tp1 in the depth signal generation mode D1, the TG1 is in a first logic level, for example, a high level of “1”, and the FD1 may receive and store a photo charge ΔQ1 generated by the PD, through the TX1. Also, during the second time period Tp3 in the depth signal generation mode D1, the TG3 is in the first logic level, for example, a high level of “1”, and the FD3 may receive and store a photo charge ΔQ3 generated by the PD, through the TX3. In this case, in addition to the photo charges ΔQ1+ΔQ3 generated by the PD, a background charge ΔQbp may be included in the charge stored in the FD1 in the depth signal generation mode D1.

The ISP 40 may measure the distance from the OB based on the photo charges ΔQ1+ΔQ3 generated by the PD and the background charge ΔQbp. The process of the ISP 40 measuring the distance from the OB will be described later.

In the color signal generation (or integration) mode D3, the PD may generate the second photo charge ΔQb based on the light energy generated by the OB. In detail, in the color signal generation mode D3, the TG3 and the TG5 are in the first logic level, for example, a high level of “1”, and the FD5 may receive and store the second photo charge ΔQb generated by the PD, through the TX3 and the TX5.

Referring back to FIGS. 1-6, the row decoder 23 may decode a row control signal, for example, an address signal, generated by the TG 32. The row driver 24 may select at least one of the row lines constituting the pixel array 22, in response to a decoded row control signal.

The CDS block 26 may perform CDS on the color signal (or a pixel signal) output from the unit pixel, for example, PX1, connected to any one of the column lines constituting the pixel array 22. In detail, the CDS block 26 may perform CDS on the color signal (or a pixel signal) output from the unit pixel, for example, PX1, connected to any one of the column lines constituting the pixel array 22, to generate a sampling signal (not shown), and may compare the sampling signal with a ramp signal Vramp to generate a digital signal according to a result of the comparison.

The output buffer 28 may buffer and output signals output from the CDS block 26 in response to a column control signal, for example, an address signal, output from the column driver 29. The column driver 29 may selectively activate at least one of the color lines of the pixel array 22 in response to a decoded control signal, for example, an address signal, output from the column decoder 30.

The column decoder 30 may decode a column control signal, for example, an address signal, generated by the TG 32. The TG 32 may generate at least one control signal to control the operation of at least one of the pixel array 22, the row decoder 23, the output buffer 28, the column decoder 29, the ramp signal generator 36, and the optical signal generator 38.

The control register block 34 may generate various commands to control constituent elements constituting the photoelectric conversion unit 20, for example, the pixel array 22, the row decoder 23, the output buffer 28, the column decoder 29, the TG 32, the ramp signal generator 36, and the optical signal generator 38. The ramp signal generator 36 may output the ramp signal Vramp to the CDS block 26 in response to a command generated by the control register block 34.

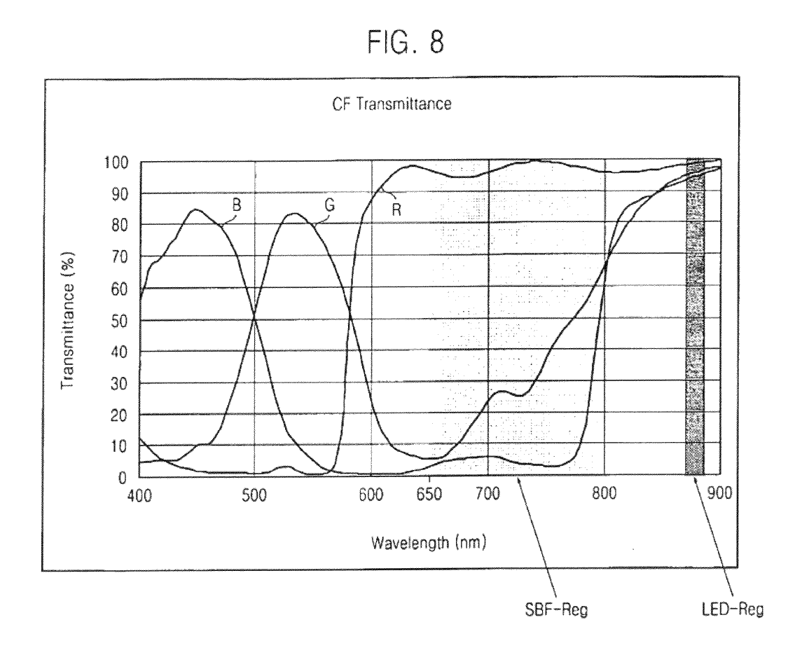

The optical signal generator 38 may be implemented by, for example, a light emitting diode (LED), a laser diode (LD), or a photodiode (PD), and may generate transmitted light to measure the distance from the OB. The wavelength of the transmitted light generated by the optical signal generator 38 may be around a band of about 870 nm, for example, LED-Reg of FIG. 8, but the example embodiments are not limited to this band.

The ISP 26 may generate a 3D image based on the at least one depth signal, for example, Vout1 and Vout3, and the color signal, for example, Vout5, detected by the photoelectric conversion unit 20. In detail, the ISP 26 may detect the distance from and the color of the OB based on the at least one depth signal, for example, Vout1 and Vout3, and the color signal, for example, Vout5, perform digital image processing based on a result of the detection, and generate a 3D image of the OB based on a result of the digital image processing. The depth signal, for example, Vout1 and Vout3, and the color signal, for example, Vout5, generated by the pixel array 22 may be analog-to-digital converted.

The ISP 26 may calculate the distance from the OB based on Equation 1.

$$\begin{matrix}L = \frac{1}{2} \times c \times \frac{Δ {Q}_{3} - Δ {Q}_{bp}}{Δ {Q}_{1} + Δ {Q}_{3} - 2 \times Δ {Q}_{bp}} \times {T}_{d} \\ = \frac{1}{2} \times c \times \frac{{V}_{out 3} - {V}_{bp}}{{V}_{out 1} + {V}_{out 3} - 2 \times {V}_{bp}} \times {T}_{d}\end{matrix} \qquad [ Equation 1 ]$$

In Equation 1, “c” is 3×108, “ΔQ₁” is the quantity of photo charges stored in the FD1 during the first time period Tp1 in the depth signal generation mode D1, “ΔQ₃” is the quantity of photo charges stored in the FD3 during the second time period Tp3 in the depth signal generation mode D1, “ΔQ_{bp}” is the quantity of background charges (BS), “T_{d}” is a delay time between the optical signal (transmitted light) and the reflected optical signal (received light), “Vₒᵤₜ₁” is the magnitude of the first depth signal generated during the first time period Tp1, “Vₒᵤₜ₃” is the magnitude of the second depth signal generated during the second time period Tp3, and “V_{bp}” is the magnitude of a signal (or a voltage) corresponding to the BS.

The ISP 26 may calculate V_{bp} by Equation 2.

$${V}_{bp} = \frac{D}{1 - 2 D} \times \frac{C 5}{C 1} \times {V}_{b} \qquad [ Equation 2 ]$$

In Equation 2, “D” is Tp/T, “T” is the time during which the depth signal generation mode D1 and the color signal generation mode D3 are performed, “C1” is the capacitance of the FD1, and “C5” is the capacitance of the FD5. The resolution of the distance from the OB calculated by Equation 1 may correspond to Equation 3.

$$Δ L ≅ \frac{c \times {T}_{d}}{4 \sqrt{{N}_{S}}} \qquad [ Equation 3 ]$$

In Equation 3, “c” is 3×108, “T_{d}” is a delay time between the transmitted light and the received light, and “N_{S}” is the intensity, or photon, of the optical signal generated by the optical signal generator 38.

The image sensing system 10 may further include a filter, for example, a stop-band filter (FT). The FT is located between the pixel array 22 and a lens LS receiving light reflected from the OB and may filter each of a transmitted light band and a color signal band.

FIG. 8 is a graph for explaining the operational characteristic of a stop band filter that may be implemented in the photoelectric converter of FIG. 1. Referring to FIG. 8, the transmittance of the wavelengths of color signals, for example, R, G, and B, input to the pixel array 22 is high in a band between about 400 nm and about 650 nm, and the transmittance of transmitted light is high in a band around 870 nm, for example, LED-Reg.

Thus, by setting the band between about 650 nm and about 800 nm, for example, SBF-Reg, as a prohibited band, the FT may filter, or stop filter, to prevent the signals having wavelengths between about 650 nm and about 800 nm, for example, the color signals R, G, and B, from being incident on the pixel array 22. That is, since the image sensing system 10 according to the present exemplary embodiment includes the FT, the signal band that does not relatively affect the generation of a depth signal and a color signal is stop filtered so that the inflow of an unnecessary signal may be prevented.

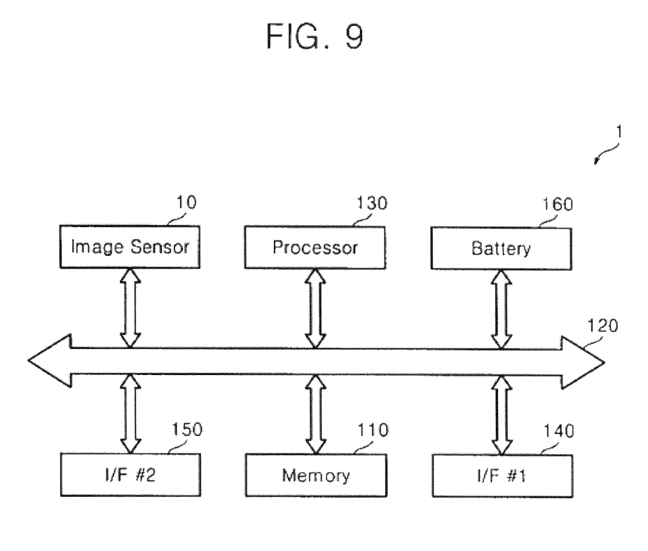

FIG. 9 is a schematic block diagram of an electronic system 1 including an image sensor according to the example embodiments. Referring to FIGS. 1 and 9, the electronic system 1 according to example embodiments may include an image sensor (or image sensing system) 10 connected to a system bus 120, a memory device 110, and a processor 130.

In this case, the electronic system 1 may be a digital camera or a mobile phone having digital camera functions. Also, the electronic system 1 according to the present exemplary embodiment may be a satellite system with a camera attached thereto.

The processor 130 may generate control signals to control the operations of the image sensor 10 and the memory device 110. The image sensor 10 may generate a 3D image of the OB as described above with reference to FIGS. 1-8, and the memory device 110 may store the 3D image.

When the electronic system 1 is implemented by a portable application according to another exemplary embodiment of the example embodiments, the electronic system 1 may further include a battery 160 to supply operation power to the image sensor 10, the memory device 110, and the processor 130. The portable application may include portable computers, digital cameras, personal digital assistances (PDAs), cellular telephones, MP3 players, portable multimedia players (PMPs), automotive navigation systems, memory cards, or electronic dictionaries.

Also, the electronic system 1 of the present exemplary embodiment may further include an interface, for example, an input/output device (I/F #1) 140, for exchanging data with an external data processing apparatus. Furthermore, when the electronic system 1 of the present exemplary embodiment is a wireless system, the electronic system 1 may further include a wireless interface (I/F #2) 150. In this case, the wireless interface 150 is connected to the processor 130 and may transmit and receive data with respect to an external wireless apparatus wirelessly via the system bus 120.

The wireless system may be a wireless device such as PDAs, portable computers, wireless telephones, pagers and digital cameras, an RF reader, or an RFID system. Also, the wireless system may be a wireless local area network (WLAN) or a wireless personal area network (WPAN). Further, the wireless system may be a cellular network.

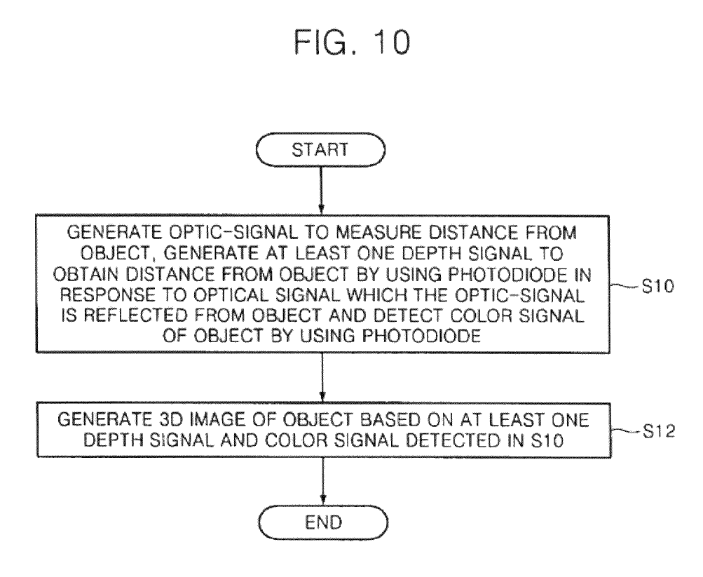

FIG. 10 is a flowchart for explaining an image sensing method according to an exemplary embodiment of the example embodiments. Referring to FIGS. 1 and 10, the photoelectric conversion unit 20 generates transmitted light, or an optical signal, to measure the distance from the OB, generates at least one depth signal to obtain the distance from the OB in response to the received light reflected from the OB, or the reflected optical signal, by using a photodiode, and detects a color signal of the OB by using the photodiode (S10). The ISP 40 generates a 3D image of the OB based on the at least one depth signal and the color signal detected by the photoelectric conversion unit 20 (S12).

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, etc. The computer readable recording medium can also be distributed over network coupled computer systems so that the computer readable code is stored and executed in a distributed fashion. Also, functional programs, codes, and code segments for accomplishing the present invention can be easily construed by programmers skilled in the art to which the present invention pertains.

As described above, according to the pixel circuit, the photoelectric converter, and the image sensing system including the pixel circuit and the photoelectric converter according to the example embodiments, during the generation of a 3D image, since a depth signal and a color signal are generated by using the same photodiode, the size of a pixel and a system may be reduced.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims example embodiments

What is claimed is:

1. A pixel circuit comprising:
a photodiode configured to generate a first photo charge to detect a distance from an object and a second photo charge to detect a color of the object; and
an output unit configured to generate at least one depth signal for detecting the distance based on the first photo charge generated by the photodiode, and configured to generate a color signal for detecting the color of the object based on the second photo charge.

2. The pixel circuit of claim 1, wherein the photodiode is configured to generate the first photo charge based on an optical signal reflected from the object.

3. The pixel circuit of claim 1, wherein the output unit comprises:
a depth signal generation unit configured to receive and store the first photo charge generated by the photodiode, and to generate the at least one depth signal based on the stored first photo charge; and
a color signal generation unit configured to receive and store the second photo charge generated by the photodiode and to generate the color signal based on the stored second photo charge.

4. The pixel circuit of claim 3, wherein the depth signal generation unit comprises:
a first transmission transistor configured to control transmission of the first photo charge generated by the photodiode to a first floating diffusion node;
a first source follower transistor connected between a power voltage and a first node, the first source follower transistor being configured to perform a first source-follower operation on the first node at the power voltage based on the charge stored in the first floating diffusion node;
a second transmission transistor configured to control transmission of the first photo charge generated by the photodiode to a second floating diffusion node; and
a second source follower transistor connected between the power voltage and a second node, the second source follower transistor being configured to perform a second source-follower operation on the second node at the power voltage based on the charge stored in the second floating diffusion node.

5. A photoelectric conversion unit comprising:
a pixel array including a plurality of pixels, wherein each of the pixels is configured to generate at least one depth signal used to detect a distance from an object and to generate a color signal to detect a color of the object; and
an image processor configured to generate a 3D image of the object based on the at least one depth signal and the color signal of the object.

6. The photoelectric conversion unit of claim 5, wherein each pixel is configured to generate a first photo charge to detect the distance from the object and a second photo charge to detect the color of the object using a photodiode, generate the at least one depth signal based on the first photo charge generated by the photodiode, and generate the color signal based on the second photo charge.

7. The photoelectric conversion unit of claim 5, wherein each pixel comprises:
a photodiode configured to generate the first photo charge to detect the distance from the object and to generate the second photo charge to detect the color of the object; and
an output unit configured to generate the at least one depth signal for detecting the distance based on the first photo charge generated by the photodiode, and the color signal for detecting the color of the object based on the second photo charge.

8. An image sensing system comprising:
a photoelectric conversion unit configured to generate an optical signal to measure a distance from an object, configured to generate at least one depth signal to obtain the distance from the object by using a photodiode in response to a reflected optical signal, the reflected optical signal being the generated optical signal reflected from the object, and the photoelectric conversion unit configured to detect a color signal of the object by using the photodiode; and
an image processor generating a 3D image of the object based on the at least one depth signal and the color signal detected by the photoelectric conversion unit.

9. The image sensing system of claim 8, further comprising:
a filter located between the photoelectric conversion unit and a lens, the filter being configured to filter each of the reflected optical signal band and the color signal band.

10. The image sensing system of claim 8, wherein the photoelectric conversion unit comprises:
a transmitted light generation unit configured to generate the generated optical signal; and
a pixel array including a plurality of pixels, wherein each of the pixels is configured to generate the at least one depth signal and the color signal in response to the reflected optical signal.
